(19) United States
(12) Patent Application Publication
(10) Pub. No.: US 2026/0130278 A1
(43) Pub. Date: May 7, 2026

(54) DIE STRUCTURE, PACKAGE STRUCTURE AND METHOD FOR FABRICATING DIE STRUCTURE

(71) Applicant: Taiwan Semiconductor Manufacturing Company, Ltd., Hsinchu (TW)

(72) Inventors: Chieh-Lung LAI, Taichung City (TW); Meng-Liang LIN, Hsinchu (TW); Hsien-Wei CHEN, Hsinchu City (TW); Kathy Wei YAN, Hsinchu (TW)

(73) Assignee: Taiwan Semiconductor Manufacturing Company, Ltd., Hsinchu (TW)

(21) Appl. No.: 18/934,412

(22) Filed: Nov. 1, 2024

(51) Int. Cl. H01L 25/065; H01L 23/31; H01L 23/538; H01L 25/00

(52) U.S. Cl. CPC H10W 90/00; H10W 70/611; H10W 74/121; H10W 90/401; H10W 90/20; H10W 90/297

(57) ABSTRACT

A die structure is provided. The die structure includes a base having a first device region and a second device region adjacent to the first device region. The die structure includes a plurality of first device cores stacked on the first device region of the base. The die structure includes a plurality of second device cores stacked on the second device region of the base. The die structure includes a top core over the first device cores and the second device cores. An interconnect structure is embedded in the top core and electrically connected to the first device cores and the second device cores. The die structure also includes a die molding material formed over the base and encapsulating the first device cores, the second device cores, and the top core.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

Although existing methods of fabricating semiconductor structures have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A through 1D illustrates cross-sectional views of intermediate steps during a process for fabricating a die structure in accordance with some embodiments.

FIGS. 2A through 2K illustrates cross-sectional views of intermediate steps during a process for fabricating a package structure in accordance with some embodiments.

FIG. 3 illustrates a cross-sectional view of the package structure in accordance with some embodiments.

FIG. 4 illustrates a plan view of the die structure in accordance with some embodiments.

FIG. 5 illustrates a plan view of the die structure in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

Embodiments of die structures, package structures and methods for fabricating the die structures are provided. The die structure includes a top core over the first device cores stacked on the first device region of the base and the second device cores stacked on the second device region of the base. An interconnect structure is embedded in the top core and electrically connected to the first device cores and the second device cores. As a result, the different stacks of device cores may be connected and operate together to enhance the performance of the die structure. In addition, since multiple stacks of device cores are integrated, the formation of the package structure can be simplified. Furthermore, a bulk top die connecting the device cores in adjacent device regions of the die structure replaces the molding material between different stacks of device cores, and therefore thermal dissipation and warpage control for the package structure may be improved.

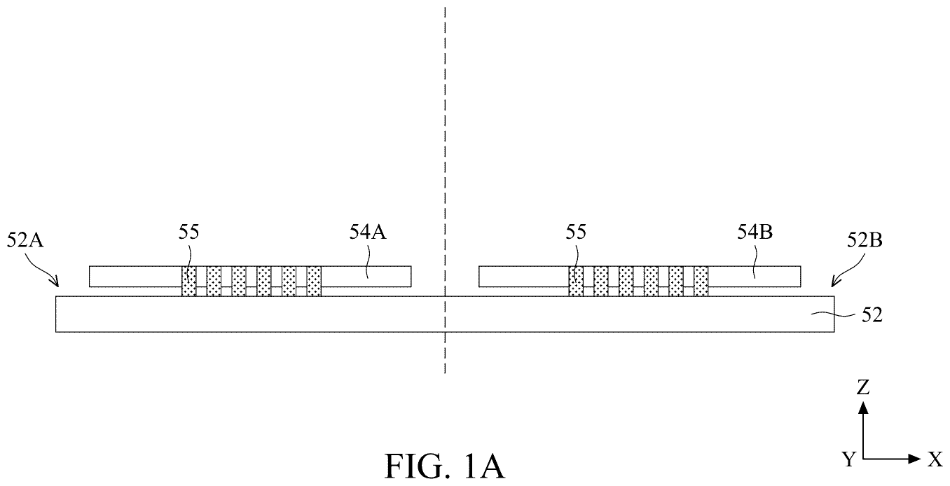

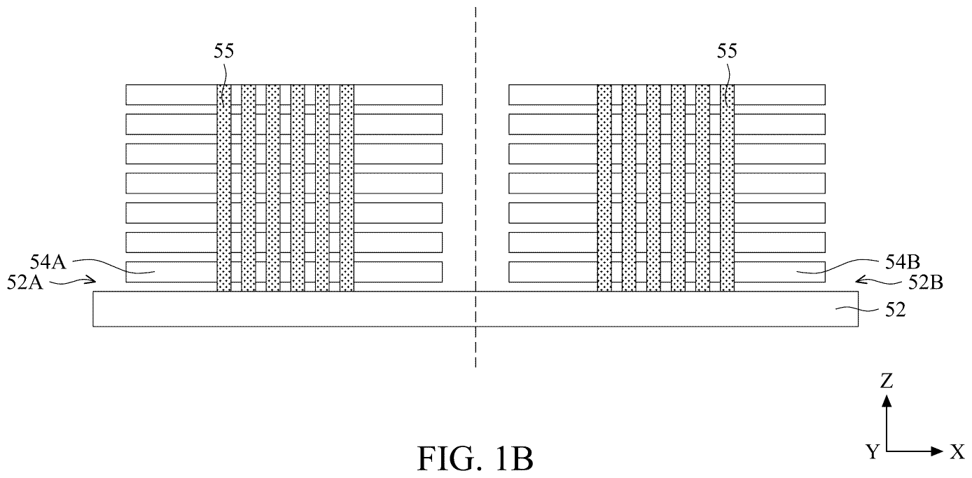

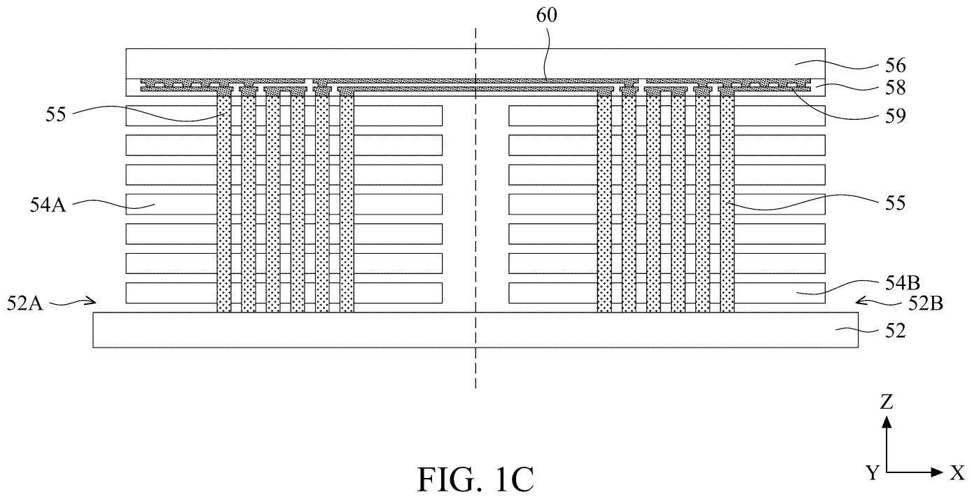

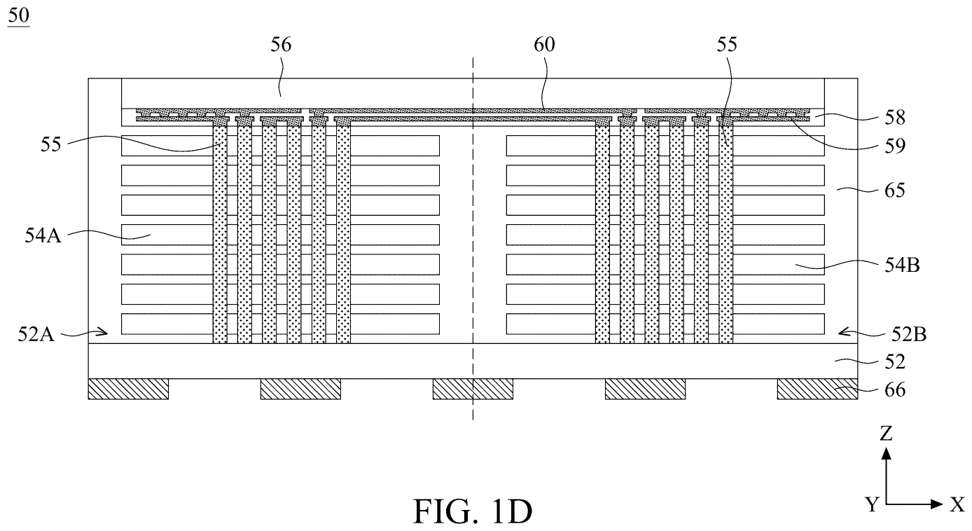

FIGS. 1A through 1D illustrates cross-sectional views of intermediate steps during a process for fabricating a die structure 50 in accordance with some embodiments. As shown in FIG. 1A, a base 52 is provided and have a first device region 52A and a second device region 52B that is adjacent to the first device region 52A. For example, the base 52 includes a semiconductor material, such as silicon, germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, a first device core 54A is disposed on the first device region 52A of the base 52, and a second device core 54B is disposed on the second device region 52B of the base 52. For example, the first device core 54A and the second device core 54B include a semiconductor material, such as silicon, germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the first device core 54A and the second device core 54B each include at least one device (not individually shown). In addition, a plurality of conductive features 55 are formed to connect the devices in the first device core 54A and the second device core 54B.

Then, as shown in FIG. 1B, a plurality of first device cores 54A are stacked on the first device region 52A of the base 52, and a plurality of second device cores 54B are stacked on the second device region 52B of the base 52. In some embodiments, a dielectric layer (not individually shown) may be sandwiched between the adjacent first device cores 54A or the adjacent second device cores 54B. The conductive features 55 are vertically aligned and electrically connected to the first device cores 54A in the first device region 52A. Similarly, the conductive features 55 are vertically aligned and electrically connected to the second device cores 54B in the second device region 52B. However, the present disclosure is not limited thereto. The conductive features 55 can be arbitrarily arranged as long as the stacked first device cores 54A or second device cores 54B are electrically connected. In some embodiments, the conductive features 55 include a conductive material, such as copper (Cu), aluminum (Al), other suitable material, or a combination thereof.

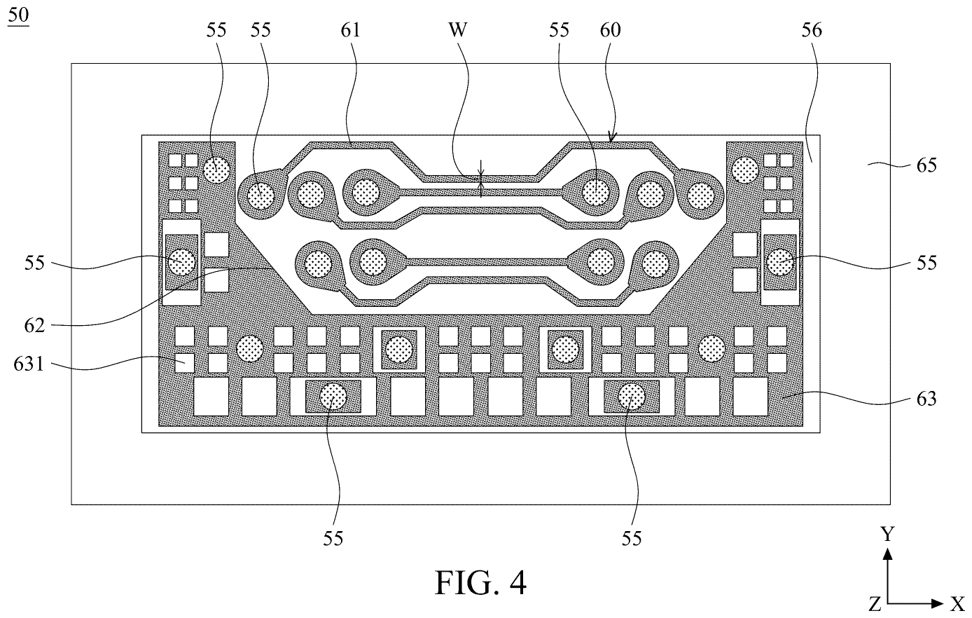

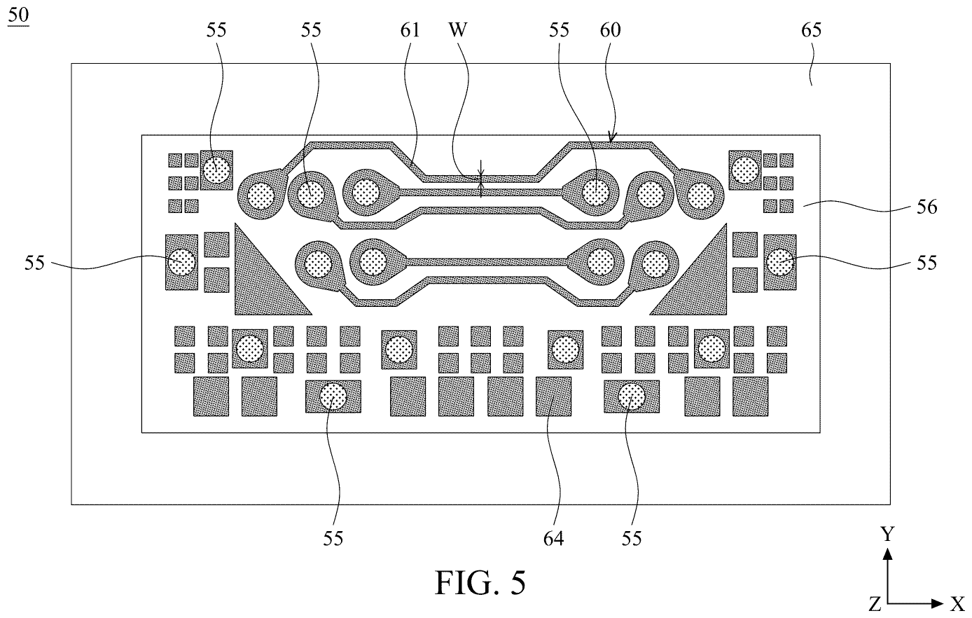

Next, as shown in FIG. 1C, a top core 56 are bonded over the first device cores 54A and the second device cores 54B. In some embodiments, the top core 56 include a substrate and at least one metallization layer 59 embedded in at least one dielectric layer 58. The substrate includes a semiconductor material, such as silicon, germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. For example, the material of the top core 56 is the same as that of the base 52. However, the present disclosure is not limited thereto. In some embodiments, an interconnect structure 60 is embedded in the top core 56 and electrically connected to the first device cores 54A and the second device cores 54B via the conductive features 55. In particular, the interconnect structure 60 may include at least one metallization layer 59 (for example, two metallization layers 59 shown in the present embodiment) embedded in at least one dielectric layer 58. The metallization layers 59 are electrically connected to the conductive features 55 in the first device region 52A and the second device region 52B. As a result, the different stacks of first device cores 54A and the second device cores 54B may be connected and operate together to enhance the performance of the die structure. The detailed structure of the interconnect structure 60 will be further discussed below in accompany with FIGS. 4 and 5.

In some embodiments, the thickness of the top core 56 is ranged from about 50 μm to about 800 μm in a direction (for example, the Z direction) that is parallel to the normal direction of the base 52. As a result, the top core 56 may have sufficient structural strength and the risk of damage or cracking in the top core 56 can be reduced. Otherwise, the top core 56 may not be too thick to impede the miniaturization of the die structure. The metallization layers in the top core 56 may help to improve the thermal conductivity of the top core 56 and strengthen the top core 56 to reduce the warpage of the package structure. In some embodiments, the thickness of each of the metallization layers in the interconnect structure 60 is ranged from about 2 μm to about 5 μm in the direction (for example, the Z direction) parallel to the normal direction of the base 52. Accordingly, the interconnect structure 60 may have sufficient structural strength to control warpage but not cause stress to the die structure.

Then, as shown in FIG. 1D, a die molding material 65 is formed over the base and encapsulates the first device cores 54A, the second device cores 54B, and the top core 56. As a result, a die structure 50 is formed. In some embodiments, the die molding material 65 is a molding compound, epoxy, or the like. In some embodiments, the die molding material 65 is applied by compression molding, transfer molding, or the like. In some embodiments, the die molding material 65 is applied in liquid or semi-liquid form and then subsequently cured. In some embodiments, a planarization step may be performed to remove and planarize a top surface of the die molding material 65. Accordingly, the top surface of the die molding material 65 is substantially level with the top surface of the top core 56. That is, the die molding material 65 exposes the top surface of the top core 56. The bulk top die 56 replaces the molding material between the first device cores 54A in the first device regions 52A and the second device cores 54B in the second device regions 52B, and therefore the thermal dissipation may be improved since an uniform thermal interface is created for the stacks of the first device cores 54A and the second device cores 54B. In addition, a plurality of connectors 66 are disposed over the base 52 for the external connection of the die structure 50.

For example, the die structure 50 may be a logic device, such as a central processing unit (CPU), a graphics processing unit (GPU), a system-on-a-chip (SoC), a microcontroller, or the like. In some other embodiments, the device die 50 may be a memory device, such as a dynamic random access memory (DRAM) die, a static random access memory (SRAM) die, a hybrid memory cube (HMC) module, a high bandwidth memory (HBM) module, or the like. For the ease of description, the die structure 50 may be referred to as the device die 50 in the following paragraphs.

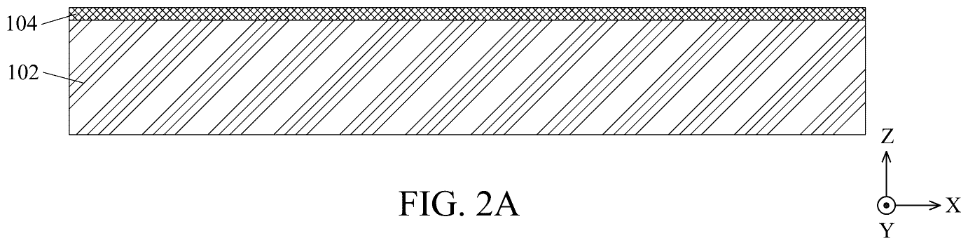

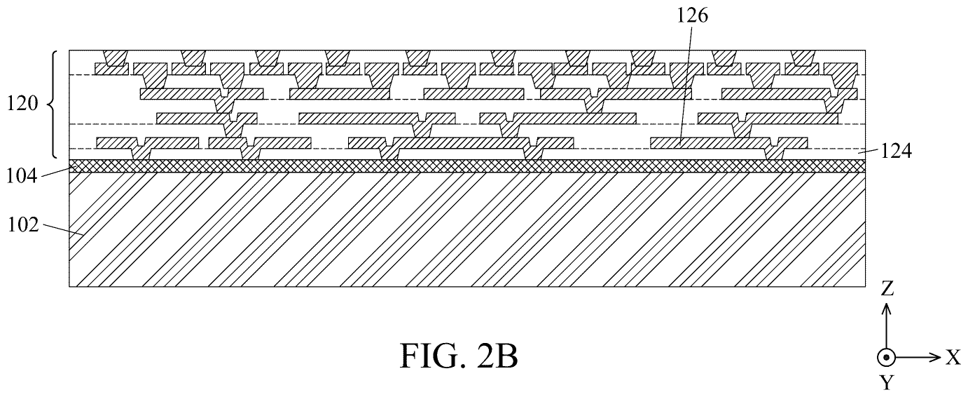

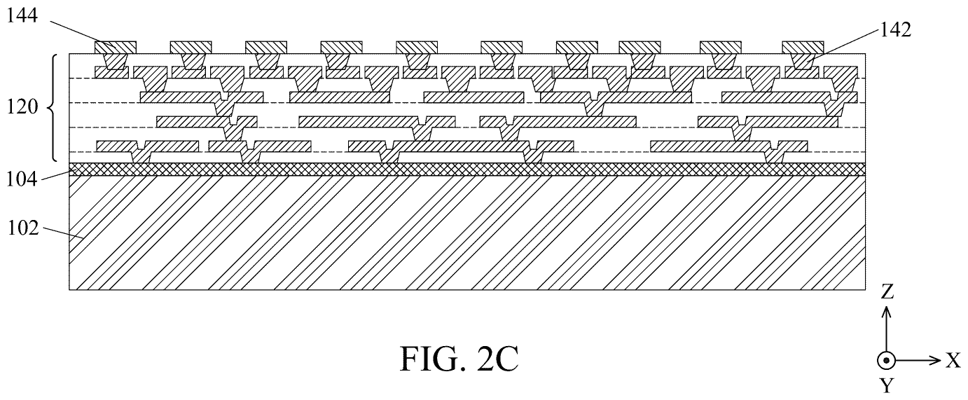

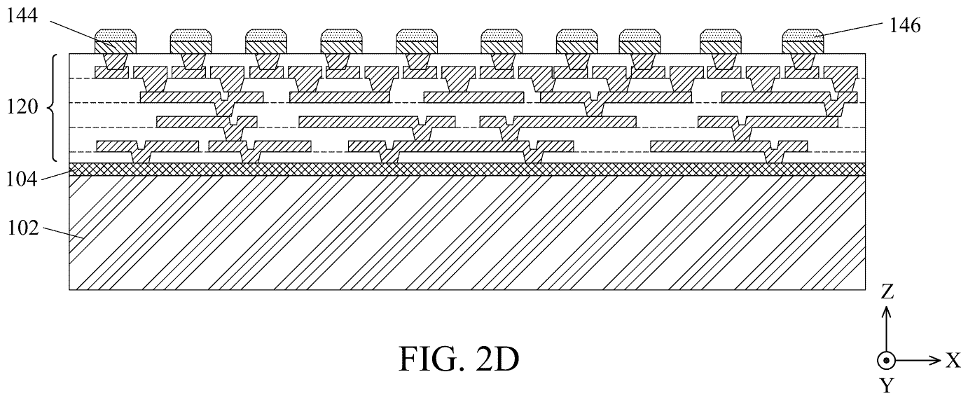

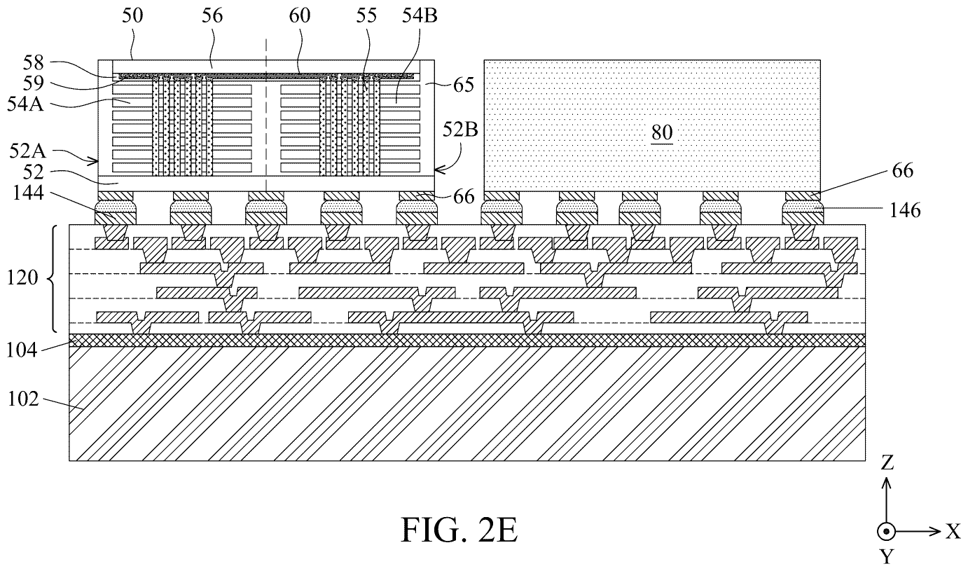

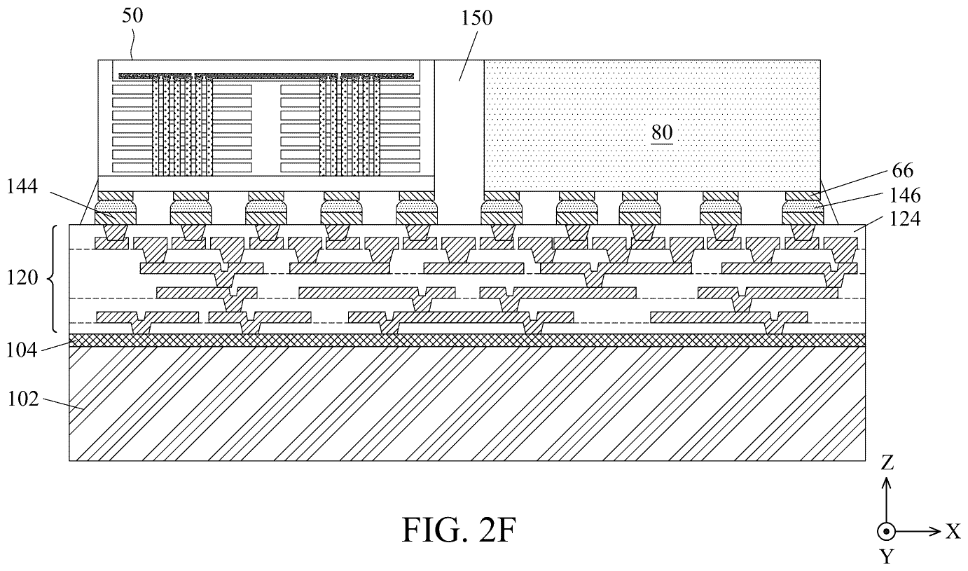

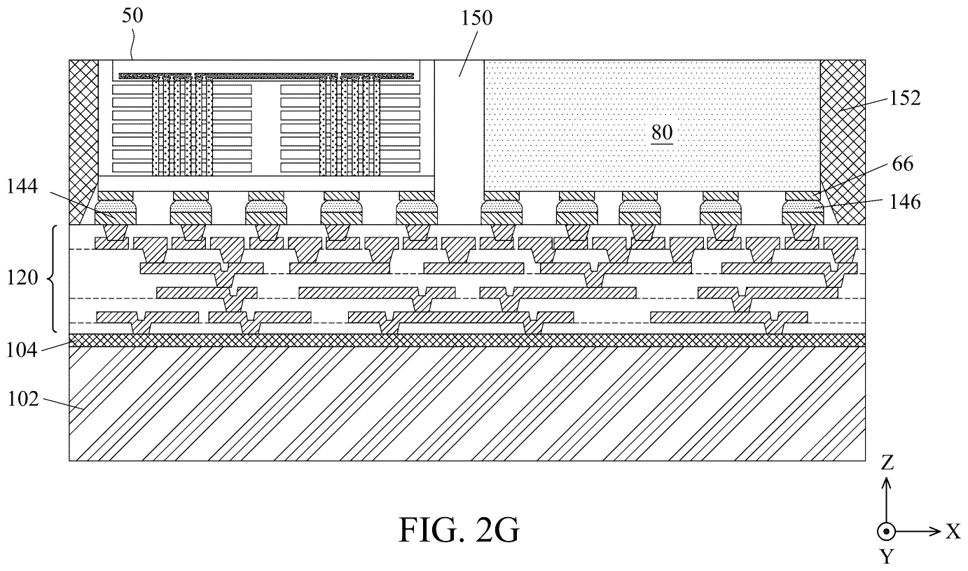

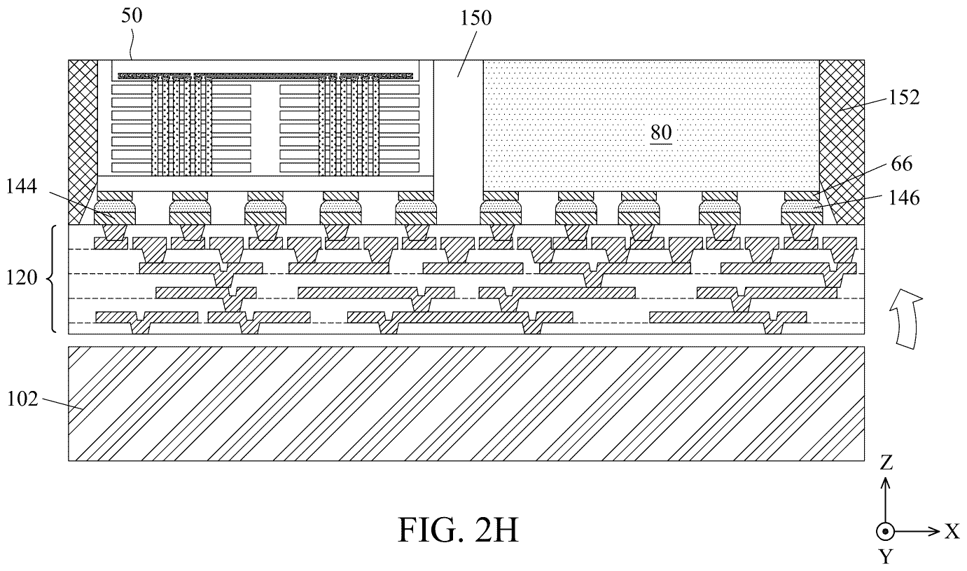

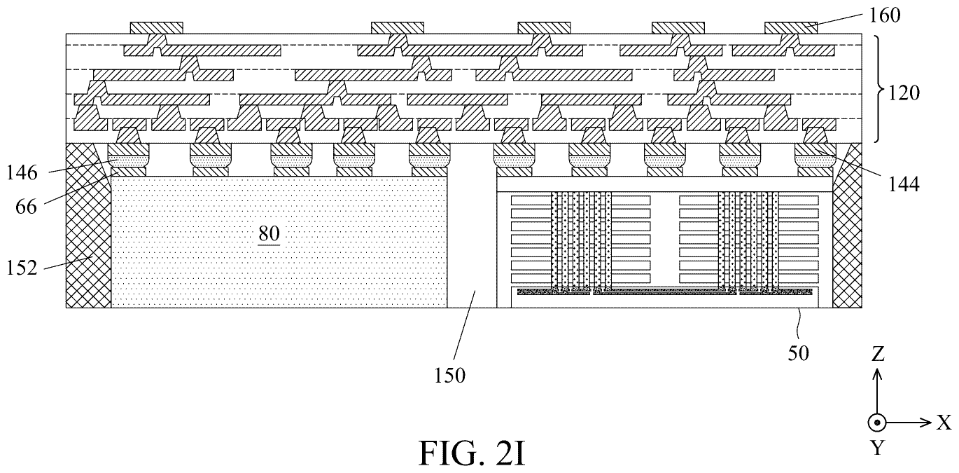

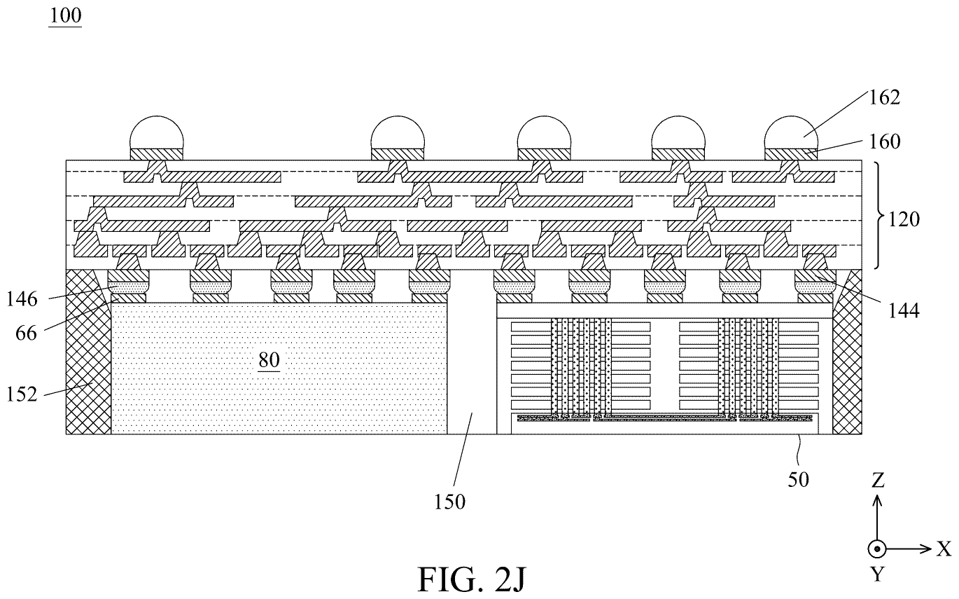

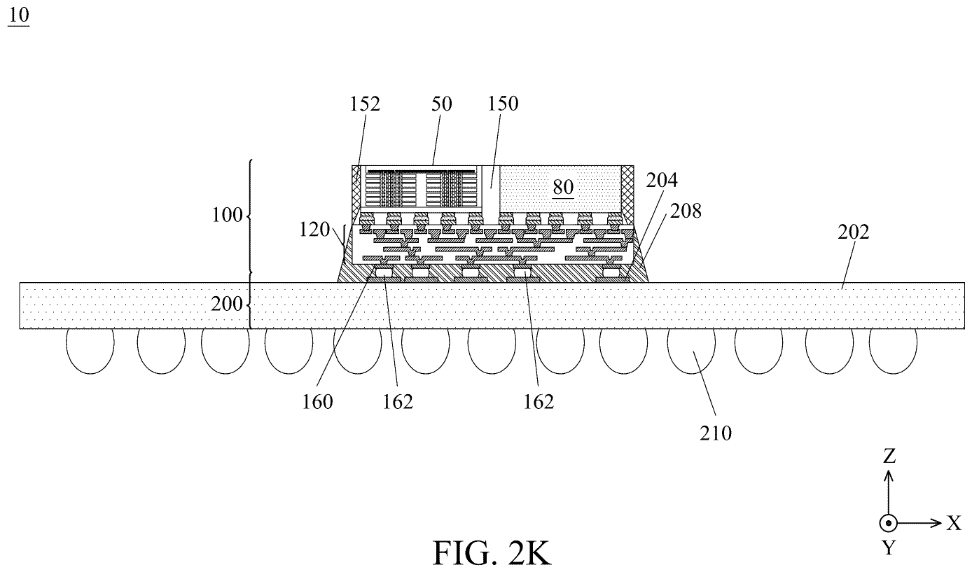

FIGS. 2A through 2K illustrate cross-sectional views of intermediate steps during a process for forming a package structure 10, in accordance with some embodiments. In some embodiments, the device dies 50 and 80 (for example, referring to FIG. 2E) are packaged to form an integrated circuit package. In some embodiments, the integrated circuit packages may also be referred to as integrated fan-out (InFO) packages. However, the present disclosure is not limited thereto. It should be noted that a plurality of first package components 100 may be formed in a wafer and singulated in the processes. For the sake of clarity and simplicity, one first package component 100 is shown in the present disclosure.

As shown in FIG. 2A, a carrier substrate 102 is provided, and a release layer 104 is formed on the carrier substrate 102. The carrier substrate 102 may be a glass carrier substrate, a ceramic carrier substrate, or the like. In some embodiments, the carrier substrate 102 includes a wafer, such that multiple packages can be formed on the carrier substrate 102 simultaneously.

In some embodiments, the release layer 104 is formed of a polymer-based material, which may be removed along with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. In some embodiments, the release layer 104 may be dispensed as a liquid and cured, may be a laminate film laminated onto the carrier substrate 102, or may be the like. In some embodiments, the top surface of the release layer 104 is leveled and has a high degree of planarity.

As shown in FIG. 2B, a redistribution structure 120 is formed over the release layer 104. In some embodiments, the metallization patterns may also be referred to as redistribution layers or redistribution lines. The redistribution structure 120 is shown as an example having multiple layers of metallization patterns 126 and dielectric layers 124 that are alternatively stacked. In some embodiments, the dielectric layer 124 is made of one or more suitable dielectric materials such as an oxide (e.g., silicon oxide), a nitride (e.g., silicon nitride), a polymer material, a polyimide material, a low-k dielectric material, a molding material (e.g., an EMC or the like), another dielectric material, or a combination thereof. In some embodiments, the dielectric layers 124 are formed by spin coating, lamination, CVD, the like, or a combination thereof. In some embodiments, the dielectric layer 124 may be patterned by an acceptable process, such as by exposing and developing the dielectric layers 124 to light when the dielectric layers 124 are a photo-sensitive material or by etching using, for example, an anisotropic etch.

In some embodiments, the metallization patterns 126 include conductive elements extending along the major surface of the dielectric layers 124 and extending through the dielectric layers 124. As an example to form the metallization pattern 126, a seed layer is formed over the dielectric layer 124 and in the openings extending through the dielectric layer 124. In some embodiments, the seed layer is a metal layer, which may be a single layer or a composite layer comprising a plurality of sub-layers formed of different materials. In some embodiments, the seed layer comprises a titanium layer and a copper layer over the titanium layer. In some embodiments, the seed layer is formed using, for example, physical vapor deposition (PVD) or the like. A photoresist is then formed and patterned on the seed layer. In some embodiments, the photoresist is formed by spin coating or the like and may be exposed to light for patterning. The pattern of the photoresist corresponds to the metallization pattern 126. The patterning forms openings through the photoresist to expose the seed layer. A conductive material is then formed in the openings of the photoresist and on the exposed portions of the seed layer. In some embodiments, the conductive material is formed by plating, such as electroplating or electroless plating, or the like. In some embodiments, the conductive material includes a metal, like copper, titanium, tungsten, aluminum, or the like. The combination of the conductive material and underlying portions of the seed layer form the metallization pattern 126. The photoresist and portions of the seed layer on which the conductive material is not formed are removed. In some embodiments, the photoresist is removed by an acceptable ashing or stripping process, such as using an oxygen plasma or the like. Once the photoresist is removed, exposed portions of the seed layer are removed, such as by using an acceptable etching process, such as by wet or dry etching.

As shown in FIG. 2C, conductive vias 142 are then formed in the redistribution structure 120. As an example to form the conductive vias 142, a seed layer is formed in the openings extending through the dielectric layer 124. In some embodiments, the seed layer is a metal layer, which is a single layer or a composite layer comprising a plurality of sub-layers formed of different materials. In some embodiments, the seed layer comprises a titanium layer and a copper layer over the titanium layer. In some embodiments, the seed layer is formed using, for example, PVD or the like. A conductive material is then formed on the seed layer in the openings. In some embodiments, the conductive material is formed by plating, such as electroplating or electroless plating, or the like. In some embodiments, the conductive material includes a metal, like copper, titanium, tungsten, aluminum, or the like. The combination of the conductive material and underlying portions of the seed layer form the conductive vias 142.

In some embodiments, under-bump metallurgies (UBMs) 144 are formed for external connection to the conductive vias 142. The UBMs 144 may be referred to as pads 144. The UBMs 144 have bump portions on and extending along the major surface of the dielectric layer 124 and physically and electrically couple the conductive vias 142. In some embodiments, the UBMs 144 are formed of the same material as the conductive vias 142. In some embodiments, the UBMs 144 includes alloys such as electroless nickel, electroless palladium, immersion gold, electroless nickel, or the like.

As shown in FIG. 2D, conductive connectors 146 are formed on the UBMs 144. In some embodiments, the conductive connectors 146 includes ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the conductive connectors 146 includes a conductive material such as solder, copper, aluminum, gold, nickel, silver, palladium, tin, the like, or a combination thereof. In some embodiments, the conductive connectors 146 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 146 comprise metal pillars (such as a copper pillar) formed by sputtering, printing, electro plating, electroless plating, CVD, or the like. In some embodiments, the metal pillars are solder free and have substantially vertical sidewalls. In some embodiments, a metal cap layer is formed on the top of the metal pillars. In some embodiments, the metal cap layer includes nickel, tin, tin-lead, gold, silver, palladium, indium, nickel-palladium-gold, nickel-gold, the like, or a combination thereof and may be formed by a plating process.

As shown in FIG. 2E, device dies 50 and 80 are attached to the structure of FIG. 2D. A desired type and quantity of device dies 50 and 80 are adopted. It should be noted that the device die 50 shown in FIG. 2E may be discussed above with reference to FIG. 1. In some embodiments, the device dies 50 and 80 are referred to as package modules. In the embodiment shown, the device dies 50 and 80 are adhered adjacent one another. For example, either of the device dies 50 and 80 may be a logic device, such as a central processing unit (CPU), a graphics processing unit (GPU), a system-on-a-chip (SoC), a system-on-integrated-chips (SoIC), a microcontroller, or the like. The other device die 50 or 80 may be a memory device, such as a dynamic random access memory (DRAM) die, a static random access memory (SRAM) die, a hybrid memory cube (HMC) module, a high bandwidth memory (HBM) module, or the like. For example, the device die 50 may be a high bandwidth memory (HBM) module with a plurality of DRAM cores, and the device die 80 may be a SoC die or a SoIC die, but the present disclosure is not limited thereto. In some embodiments, the device dies 50 and 80 are formed in the processes of the same technology node, or they are formed in the processes of different technology nodes. For example, one of the device dies 50 and 80 may be of a more advanced process node than the other of the device dies 50 and 80. The device dies 50 and 80 may be different sizes (e.g., different heights and/or surface areas), or they may be the same size (e.g., the same height and/or surface area). Since multiple stacks of first device cores 54A and the second device cores 54B are integrated as a single device die 50, the formation of the package structure can be simplified.

In some embodiments, the device dies 50 and 80 are attached to the conductive connectors 146. That is, the die connectors 66 of the device dies 50 are connected to the conductive connectors 146 opposite the UBMs 144. In some embodiments, the conductive connectors 146 are reflowed to attach the device dies 50 and 80 to the UBMs 144. The conductive connectors 146 electrically and/or physically couple the redistribution structure 120, including metallization patterns in the redistribution structure 120, to the device dies 50 and 80.

In some embodiments, the conductive connectors 146 have an epoxy flux (not shown) formed thereon before they are reflowed with at least some of the epoxy portion of the epoxy flux remaining after the device dies 50 and 80 are attached to the redistribution structure 120. This remaining epoxy portion may act as an underfill to reduce stress and protect the joints resulting from reflowing the conductive connectors 146.

As shown in FIG. 2F, an underfill 150 is formed between the device dies 50, the dummy dies 70, and the dielectric layer 124, including between and around the UBMs 144, the conductive connectors 146, and the die connectors 66. In some embodiments, the underfill 150 is formed by a capillary flow process after the device dies 50 and 80 are attached or is formed by a suitable deposition method before the device dies 50 and 80 are attached. In some embodiments, the underfill 150 is also between the device dies 50 and 80. In some embodiments, the underfill 150 may fill the gap between adjacent two of the device dies 50 and 80. However, the present disclosure is not limited thereto.

As shown in FIG. 2G, a package molding material 152 is formed around the device dies 50 and 80, the conductive connectors 146, and the underfill 150. After formation, the package molding material 152 encapsulates the conductive connectors 146, the device dies 50 and 80. In some embodiments, the package molding material 152 is a molding compound, epoxy, or the like. In some embodiments, the package molding material 152 is applied by compression molding, transfer molding, or the like. In some embodiments, the package molding material 152 is applied in liquid or semi-liquid form and then subsequently cured. In some embodiments, a planarization step may be performed to remove and planarize an upper surface of the package molding material 152. In some embodiments, surfaces of the underfill 150, the package molding material 152, the device dies 50 and 80 are coplanar (within process variation).

As shown in FIG. 2H, a carrier substrate de-bonding is performed to detach (or “de-bond”) the carrier substrate 102 from the redistribution structure 120, e.g., the dielectric layer 124. In accordance with some embodiments, the de-bonding includes projecting a light such as a laser light or an UV light on the release layer 104 so that the release layer 104 decomposes under the heat of the light and the carrier substrate 102 can be removed. The structure is then flipped over and placed on a tape (not shown).

As shown in FIG. 2I, UBMs 160 are formed for external connection to the redistribution structure 120, e.g., the metallization pattern 126. The UBMs 160 have bump portions on and extending along the major surface of the dielectric layer 124. In some embodiments, the UBMs 160 are formed of the same material as the metallization pattern 126.

As shown in FIG. 2J, conductive connectors 162 are formed on the UBMs 160. The conductive connectors 162 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the conductive connectors 162 include a conductive material such as solder, copper, aluminum, gold, nickel, silver, palladium, tin, the like, or a combination thereof. In some embodiments, the conductive connectors 162 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 162 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. Accordingly, the first package component 100 is formed.

As shown in FIG. 2K, the first package component 100 may be mounted on the second package component 200 using the conductive connectors 162. The second package component 200 includes a package substrate 202 and bond pads 204 over the package substrate 202. In some embodiments, the package substrate 202 is made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, in some embodiments, the package substrate 202 is a semiconductor-on-insulator (SOI) substrate. Generally, an SOI substrate includes a layer of a semiconductor material such as epitaxial silicon, germanium, silicon germanium, SOI, SGOI, or combinations thereof. The package substrate 202 is, in one alternative embodiment, based on an insulating core such as a fiberglass reinforced resin core. One example core material is fiberglass resin. Alternatives for the core material include bismaleimide-triazine (BT) resin, or alternatively, other PCB materials or films. Build up films or other laminates may be used for package substrate 202.

In some embodiments, the second package component 200 includes bump structures 210. In some embodiments, the bump structures 210 may be conductive ball structures (such as ball grid array (BGA)), conductive pillar structures, or conductive paste structures that are mounted on and electrically coupled to the package substrate 202 in the bonding process.

The package substrate 202 may also include metallization layers and vias (not shown), with the bond pads 204 being physically and/or electrically coupled to the metallization layers and vias. In some embodiments, the metallization layers are formed over the active and passive devices and are designed to connect the various devices to form functional circuitry. In some embodiments, the metallization layers are formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the package substrate 202 is substantially free of active and passive devices.

In some embodiments, the conductive connectors 162 are reflowed to attach the first package component 100 to the bond pads 204. The conductive connectors 162 electrically and/or physically couple the second package component 200, including metallization layers in the package substrate 202, to the first package component 100. In some embodiments, the conductive connectors 162 have an epoxy flux (not shown) formed thereon before they are reflowed with at least some of the epoxy portion of the epoxy flux remaining after the first package component 100 is attached to the second package component 200. This remaining epoxy portion may act as an underfill to reduce stress and protect the joints resulting from reflowing the conductive connectors 162. In some embodiments, an underfill 208 is formed between the first package component 100 and the second package component 200 and surrounding the conductive connectors 162. In some embodiments, the underfill 208 is formed by a capillary flow process after the second package component 200 is attached or may be formed by a suitable deposition method before the second package component 200 is attached. As a result, the package structure 10 is formed.

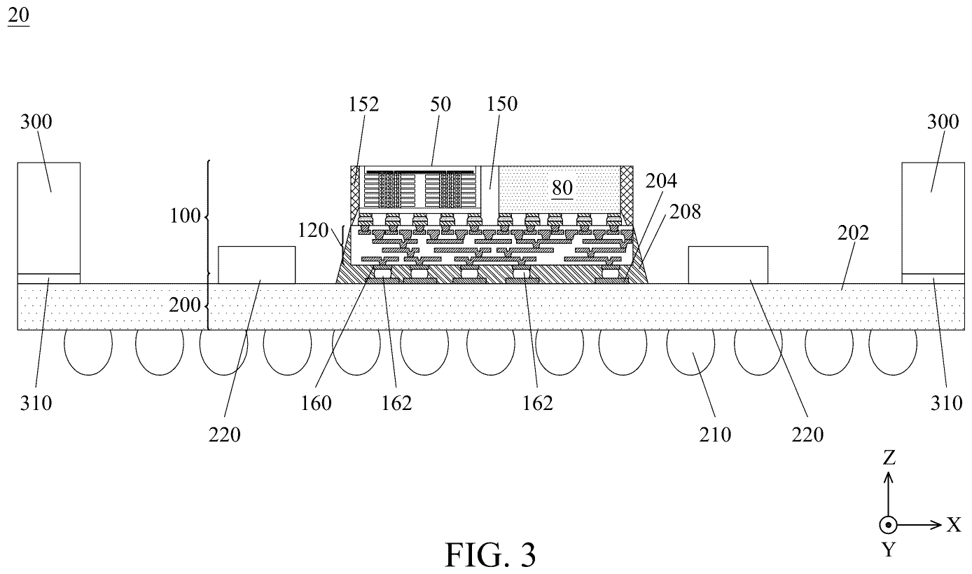

FIG. 3 illustrates a cross-sectional view of the package structure 20 in accordance with some embodiments. It should be noted that the package structure 20 shown in FIG. 3 may include portions or elements that are the same or similar to those of the package structure 10 shown in FIG. 2K. These portions or elements will be denoted by the same or similar numerals, and will not be discussed in detail for the sake of brevity. As shown in FIG. 3, one or more electronic component 220 is formed on the second package component 200. The electronic component 220 is bonded to and exposed from the package substrate 202. In some embodiments, the electronic component 220 is embedded in the package substrate 202. In some embodiments, the electronic component 220 may be active and/or passive devices. In some embodiments, the electronic component 220 is spaced apart from the underfill 208. For example, the electronic component 220 may be a wide variety of devices such as transistors, capacitors, resistors, combinations of these, and the like may be used to generate the structural and functional requirements of the design for the device stack. In some embodiments, the electronic components are formed using any suitable methods.

In addition, as shown in FIG. 3, a ring structure 300 is bonded to the second package component 200 (in particular, the package substrate 202) via an adhesive film 310. As a result, the package structure 20 is formed. In some embodiments, the ring structure 300 is configured to reduce the warpage of the package structure 20 and protect the electronic component 220. It should be noted that the package structure 20 may also include other components to achieve desired functions, and these configurations are also contemplated within the scope of the present disclosure.

FIG. 4 illustrates a plan view of the die structure 50 in accordance with some embodiments. As shown in FIG. 4, the interconnect structure 60 includes a plurality of connecting wires 61, each of which is connected to one of the conductive features 55 in the first device region 52A (for example, on the left-hand side) and one of the conductive features 55 in the second device region 52B (for example, on the right-hand side). In some embodiments, the width W of the connecting wires 61 is less than or equal to about 10 μm in a direction (for example, the Y direction) that is perpendicular to the normal direction of the base 52. In some embodiments, the connecting wires may extend in different directions that are not parallel to each other. With the above configuration, the first device cores 54A can be connected to the second device cores 54B, and therefore the performance of the die structure 50 may be enhanced.

In some embodiments, the interconnect structure 60 includes a bulk portion 63 that is located around the connecting wires 61, and the bulk portion 63 extends over the first device region 52A and the second device region 52B. For example, the bulk portion 63 may be located on three sides of the connecting wires 61, but the present disclosure is not limited thereto. The arrangement of the bulk portion 63 may help to improve the thermal conductivity of the top core 56 and strengthen the top core 56 to reduce the warpage of the package structure 10. In some embodiments, in the plan view, the ratio of the area of the metallization layer of the interconnect structure 60 to the area of the top core 56 is ranged from about 40% to about 80% so as to achieve the above positive effects (for example, better thermal dissipation, warpage control, etc.) without causing severe stress in the die structure 50.

In some embodiments, a plurality of openings 631 are formed in the bulk portion 63. The shape of the openings 631 may be different from each other, and may be arranged as an array to form a mesh structure. However, the present disclosure is not limited thereto. All the possible sizes, shapes, and the locations of the openings 631 are included within the scope of the present disclosure. With the arrangement of the openings 631, the stress may be relieved in the die structure 50. In some embodiments, the bulk portion 63 includes a chamfer structure 62 facing the connecting wires 61. In this way, the area of the interconnect structure 60 in the top core 56 may be increased, thereby the thermal dissipation of the die structure 50 and the warpage control of the package structure 10 can be improved. In some embodiments, the conductive features 55 are electrically connected to the bulk portion 63. As a result, the circuit design flexibility for the die structure 50 may be improved. However, the present disclosure is not limited thereto. In some embodiments, the bulk portion 63 can be electrically isolated from the conductive features 55 and therefore serves as a dummy pattern around the conductive features 55 and the connecting wires 61.

FIG. 5 illustrates a plan view of the die structure 50 in accordance with some embodiments. As shown in FIG. 5, the interconnect structure 60 includes a plurality of dummy patterns 64 that are located around and electrically isolated from the connecting wires 61. As a result, the area of the interconnect structure 60 in the top core 56 may be increased, thereby the thermal dissipation of the die structure 50 and the warpage control of the package structure 10 can be improved. It should be noted that the sizes and shapes of the dummy patterns 64 may be different from each other, and may be arranged arbitrarily. All the possible sizes, shapes (for example, rectangle, triangle, circle, polygon, any other regular or irregular shapes), and the locations of the dummy patterns 64 are included within the scope of the present disclosure.

Embodiments of die structures, package structures and methods for fabricating the die structures are provided. The die structure includes a top core over the first device cores stacked on the first device region of the base and the second device cores stacked on the second device region of the base. An interconnect structure is embedded in the top core and electrically connected to the first device cores and the second device cores. As a result, the different stacks of device cores may be connected and operate together to enhance the performance of the die structure. In addition, since multiple stacks of device cores are integrated, the formation of the package structure can be simplified. Furthermore, a bulk top die connecting the device cores in adjacent device regions of the die structure replaces the molding material between different stacks of device cores, and therefore thermal dissipation and warpage control for the package structure may be improved. In some embodiments, in the plan view, the ratio of the area of the metallization layer of the interconnect structure to the area of the top core is ranged from about 40% to about 80% so as to achieve better thermal dissipation and warpage control without causing severe stress in the die structure. For example, a plurality of openings and/or chamfer structures can be disposed in the interconnect structure for tuning the area ratio of the interconnect structure to the top core.

In some embodiments, a die structure is provided. The die structure includes a base having a first device region and a second device region adjacent to the first device region. The die structure includes a plurality of first device cores stacked on the first device region of the base. The die structure includes a plurality of second device cores stacked on the second device region of the base. The die structure includes a top core over the first device cores and the second device cores. An interconnect structure is embedded in the top core and electrically connected to the first device cores and the second device cores. The die structure also includes a die molding material formed over the base and encapsulating the first device cores, the second device cores, and the top core.

In some embodiments, a package structure is provided. The package structure includes a device die bonded to a package substrate. The device die includes a base having a first device region and a second device region adjacent to the first device region. The device die includes a plurality of first device cores stacked on the first device region of the base and a plurality of second device cores stacked on the second device region of the base. The device die includes a top core over the first device cores and the second device cores. An interconnect structure is embedded in the top core and electrically connected to the first device cores and the second device cores. In the plan view, the ratio of the area of the interconnect structure to the area of the top core is ranged from about 40% to about 80%. The device die includes a die molding material formed over the base and encapsulating the first device cores, the second device cores. The die molding material exposes the top surface of the top core. The package structure also includes a package molding material over the package substrate and around the device die.

In some embodiments, a method for fabricating a die structure is provided. The method includes stacking a plurality of first device cores over a first device region of a base. The method includes stacking a plurality of second device cores over a second device region of the base, wherein the first device region is adjacent to the second device region. The method includes bonding a top core over the first device cores and the second device cores. An interconnect structure is embedded in the top core and electrically connected to the first device cores and the second device cores. The method also includes forming a die molding material formed over the base and encapsulating the first device cores, the second device cores. The top surface of the die molding material is substantially level with the top surface of the top core.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A die structure, comprising:
a base having a first device region and a second device region adjacent to the first device region;
a plurality of first device cores stacked on the first device region of the base;
a plurality of second device cores stacked on the second device region of the base;
a top core over the first device cores and the second device cores, wherein an interconnect structure is embedded in the top core and electrically connected to the first device cores and the second device cores; and
a die molding material formed over the base and encapsulating the first device cores, the second device cores, and the top core.

2. The die structure as claimed in claim 1, further comprising:
a first plurality of conductive features electrically connected to the first device cores; and
a second plurality of conductive features electrically connected to the second device cores, wherein the first plurality and the second plurality of conductive features are electrically connected to the interconnect structure in the top core.

3. The die structure as claimed in claim 2, wherein the interconnect structure comprises a connecting wire connected to one of the first plurality of conductive features and one of the second plurality of conductive features.

4. The die structure as claimed in claim 3, wherein a width of the connecting wire is less than or equal to about 10 μm in a direction perpendicular to a normal direction of the base.

5. The die structure as claimed in claim 3, wherein the connecting wire extends in different directions that are not parallel to each other.

6. The die structure as claimed in claim 3, wherein the interconnect structure comprises a bulk portion located around the connecting wire, and the bulk portion extends over the first device region and the second device region.

7. The die structure as claimed in claim 6, wherein a plurality of openings are formed in the bulk portion.

8. The die structure as claimed in claim 6, wherein the bulk portion comprises a chamfer structure facing the connecting wire.

9. The die structure as claimed in claim 6, wherein the first plurality and the second plurality of conductive features are electrically connected to the bulk portion.

10. The die structure as claimed in claim 3, wherein the interconnect structure comprises a plurality of dummy patterns electrically isolated from the connecting wire.

11. A package structure, comprising:
a device die bonded to a package substrate, wherein the device die comprises:
a base having a first device region and a second device region adjacent to the first device region;
a plurality of first device cores stacked on the first device region of the base;
a plurality of second device cores stacked on the second device region of the base;
a top core over the first device cores and the second device cores, wherein an interconnect structure is embedded in the top core and electrically connected to the first device cores and the second device cores; and
a die molding material formed over the base and encapsulating the first device cores, the second device cores, wherein the die molding material exposes a top surface of the top core; and
a package molding material over the package substrate and around the device die.

12. The package structure as claimed in claim 11, wherein in a plan view, a ratio of an area of the interconnect structure to an area of the top core is ranged from about 40% to about 80%.

13. The package structure as claimed in claim 11, wherein the interconnect structure comprises a plurality of metallization layers, and a thickness of each of the metallization layers is ranged from about 2 μm to about 5 μm in a direction parallel to a normal direction of the base.

14. The package structure as claimed in claim 11, wherein a thickness of the top core is ranged from about 50 μm to about 800 μm in a direction parallel to a normal direction of the base.

15. A method for fabricating a die structure, comprising:
stacking a plurality of first device cores over a first device region of a base;
stacking a plurality of second device cores over a second device region of the base, wherein the first device region is adjacent to the second device region;
bonding a top core over the first device cores and the second device cores, wherein an interconnect structure is embedded in the top core and electrically connected to the first device cores and the second device cores; and
forming a die molding material formed over the base and encapsulating the first device cores, the second device cores, wherein a top surface of the die molding material is substantially level with a top surface of the top core.

16. The method as claimed in claim 15, further comprising:
forming a first plurality of conductive features electrically connected to the first device cores; and
forming a second plurality of conductive features electrically connected to the second device cores, wherein the first plurality and the second plurality of conductive features are electrically connected to the interconnect structure in the top core.

17. The method as claimed in claim 15, further comprising:
forming the interconnect structure in the top core before the top core is bonded over the first device cores and the second device cores, wherein forming the interconnect structure comprises forming a metallization layer in the top core, and in a plan view, a ratio of an area of the metallization layer to an area of the top core is ranged from about 40% to about 80%.

18. The method as claimed in claim 17, wherein forming the interconnect structure in the top core further comprises:
forming a connecting wire connected to one of the first plurality of conductive features and one of the second plurality of conductive features.

19. The method as claimed in claim 18, wherein forming the interconnect structure in the top core further comprises:
forming a bulk portion around the connecting wire, wherein the bulk portion extends over the first device region and the second device region, and a plurality of openings are formed in the bulk portion.

20. The method as claimed in claim 17, wherein forming the interconnect structure in the top core further comprises:
forming a plurality of dummy patterns located around and electrically isolated from the connecting wire.
